(19) United States
(12) Patent Application Publication
(10) Pub. No.: US 2008/0160786 A1
(43) Pub. Date: Jul. 3, 2008

(54) METHOD FOR INCREASING FILM STRESS AND METHOD FOR FORMING HIGH STRESS LAYER

(75) Inventors: Neng-Kuo Chen, Hsinchu city (TW); Teng-Chun Tsai, Hsinchu city (TW); Chien-Chung Huang, Taichung Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: UNITED MICROELECTRONICS CORP., Hsinchu (TW)

(21) Appl. No.: 11/616,286

(22) Filed: Dec. 27, 2006

(51) Int. Cl. H01L 21/469

(52) U.S. Cl. 438/791; 257/E21.487

(57) ABSTRACT

A method for forming a high stress layer is provided. According to the method, a substrate is put into a reactor of a PECVD machine and a reaction gas is added into the reactor. Then, an assistant reaction gas which has the molecular weight greater than or equal to the molecular weight of nitrogen gas is added into the reactor. Next, a carrier gas which has the molecular weight smaller than the molecular weight of nitrogen gas is added into the reactor to increase the bombarding efficiency in film deposition. Thereby, the high stress layer is formed on the substrate.

### BACKGROUND OF THE INVENTION

1. Field of the Invention

The present invention relates to a method for forming a stress layer. More particularly, the present invention relates to a method for increasing film stress and a method for forming a high stress layer.

2. Description of Related Art

Along with semiconductor fabricating process entering an era of deep submicron, increasing the driving current of NMOS device and PMOS device has been more and more focused on. In particular, as to the process beyond present 65 nm, time delay and operation rate of the device can be improved considerably by increasing the driving current of NMOS and PMOS effectively.

Recently, various methods for increasing device driving current using internal stress have been provided in the industry, wherein the methods include increasing stress of shallow trench isolation oxide (STI Oxide), polysilicon cap silicon nitride (Poly-cap SiN) layer, and contact silicon nitride stop layer film etc. When the tensile stress of the foregoing various films is increased, the driving current in n-channel region increases. When the compressive stress of the foregoing various films is increased, the driving current in p-channel region increases.

Generally speaking, the thin film deposition technology presently used in the industry cannot meet the requirement of IC process. For example, the stress of the silicon nitride layer formed with the conventional plasma-enhanced chemical vapor deposition (PECVD) technology can only reach about −0.06 GPa. It is provided by the industry that an inert gas of greater molecular weight is added into conventional PECVD technology to increase the stress of the deposited film up to about −2.4 GPa, however, this is still not sufficient for the stress value required by process of 65 nm or below. Besides, since a gas of greater molecular weight is added for increasing the film stress in deposition process, bombard power consumption may be caused and the deposition efficiency is reduced due to the collisions between the gas atoms and the collisions of the gas with the nitrogen carrier gas used in conventional PECVD technology.

Accordingly, how to develop a technology of forming high stress layer has become one of the most important subjects in the relative industry.

### SUMMARY OF THE INVENTION

Accordingly, the present invention is directed to provide a method for increasing film stress, which can prevent the collision between the gas atoms in a plasma-enhanced chemical vapor deposition (PECVD) operation from affecting the efficiency of deposition and can increase the film stress.

According to another aspect of the present invention, a method for forming a high stress layer is provided to improve the performance of the device.

The present invention provides a method for increasing film stress, and the method is suitable for forming a stress layer in a PECVD operation. According to the method, when performing a PECVD process, a carrier gas which has the molecular weight smaller than the molecular weight of nitrogen gas and an assistant reaction gas which has the molecular weight greater than or equal to the molecular weight of nitrogen gas are added so as to perform an ion bombard process.

According to the method of increasing film stress in an embodiment of the present invention, the assistant reaction gas is, for example, Ar, N₂, Kr, or Xe.

According to the method of increasing film stress in an embodiment of the present invention, the carrier gas is, for example, H₂, He, Ne, or the combination thereof.

According to the method of increasing film stress in an embodiment of the present invention, the high stress layer is, for example, a silicon nitride layer.

According to the method of increasing film stress in an embodiment of the present invention, before the PECVD process is performed, a pre-gas is added. The pre-gas comprises N₂ or H₂.

The present invention further provides a method for forming a high stress layer. According to the method, a substrate is put into a reactor of a PECVD machine and adding a reaction gas into the reactor. Then, an assistant reaction gas, which has the molecular weight greater than or equal to the molecular weight of nitrogen gas, is added into the reactor. Next, a carrier gas which has the molecular weight smaller than the molecular weight of nitrogen gas is added into the reactor so that the high stress layer is formed on the substrate.

According to the method for forming high stress layer in an embodiment of the present invention, the assistant reaction gas is, for example, Ar, N₂, Kr, or Xe.

According to the method for forming high stress layer in an embodiment of the present invention, the carrier gas is, for example, H₂, He, Ne, or the combination thereof.

According to the method for forming high stress layer in an embodiment of the present invention, the high stress layer is, for example, a silicon nitride layer, and the reaction gases used are, for example, SiH₄ and NH₃.

According to the method for forming high stress layer in an embodiment of the present invention, before the reaction gas is added into the reactor, a pre-gas is added. The pre-gas comprises N2 or H2.

According to the methods in the present invention, a high stress layer is formed by using a PECVD machine, and the film stress is increased by adding an assistant reaction gas of greater molecular weight. Moreover, according to the methods in the present invention, collisions between atoms of the assistant reaction gas are reduced by adding a carrier gas having smaller molecular weight than nitrogen gas so that bombard power consumption can be reduced and deposition efficiency can be increased, and furthermore, the stress value of the deposited stress layer can be further increased.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional diagram of a CMOS device according to an embodiment of the present invention.

FIG. 2 is a diagram illustrating the relationship between the threshold current gate percentage of the device and the stress value of the stress layer.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In the manufacturing process of IC device, the driving current of a device can be improved effectively by increasing the stress of the shallow trench isolation oxide (STI Oxide) layer, the polysilicon cap silicon nitride (Poly-cap SiN) layer, and the contact silicon nitride stop layer film etc.

A stress of the film is increased by the methods in the present invention so as to form a high stress layer, and can improve the performance of the device accordingly. Below, the present invention will be described with the example of forming a high compressive stress silicon nitride layer.

Generally, before the PECVD process is performed, a pre-gas is added into the reactor to reach the pressure in the reactor equipment. The pre-gas is, for example, N₂. In one embodiment, the pre-gas also comprises H₂.

Next, after the pressure in the reactor is stabilized, a silicon substrate or a base material having been formed with a plurality of material layers thereon is put into a plasma-enhanced chemical vapor deposition (PECVD) machine, and the temperature is raised to be between 300° C. and 600° C., for example, 400° C. The high-frequency source power is set to be between 50 W to 1,000 W, for example, 75 W, and the low-frequency source power is set to between 50 W to 1,000 W, for example, 75 W. Silane (SiH₄) and ammonia (NH₃) are passed into the reactor of the foregoing PECVD machine as the reaction gas, wherein the flow rate of SiH₄ may be between 30 sccm to 1,000 sccm, for example, 60 sccm, and the flow rate of NH₃ may be between 30 sccm to 1,000 sccm, for example, 150 sccm.

Then, an assistant reaction gas is passed into the reactor of the PECVD machine, wherein the molecular weight of the assistant reaction gas is greater than or equal to the molecular weight of nitrogen gas, and the assistant reaction gas may be, for example, Ar, N₂, Kr, or Xe. In the present embodiment, Ar is used as the assistant reaction gas, and the flow rate thereof may be between 300 sccm to 5,000 sccm, for example, 3,000 sccm. The function of the assistant reaction gas is to increase the ion bombard at thin film deposition, which is useful to deposit more dense film and so as to increase the stress value of the deposited silicon nitride layer. Here, adjustment of process factors is further included so that a stable pressure, for example, between 100 mTorr to 20 Torr is reached in the reactor of the PECVD machine. On the other hand, even though the assistant reaction gas can help to increase the film stress, however, the molecular weight of the assistant reaction gas is large, so that the collisions between the atoms of the assistant reaction gas may affect the entire efficiency of ion bombard, and accordingly, the stress value of the thin film cannot be further increased.

Next, a carrier gas is conducted into the reactor, and the molecular weight of the carrier gas is smaller than the molecular weight of nitrogen gas. The carrier gas may be, for example, H₂, He, Ne, or the combination thereof. In the present embodiment, H₂ is used as the carrier gas, and the flow rate thereof may be between 500 sccm to 5,000 sccm, for example, 1,000 sccm. The deposition of the silicon nitride layer is started after the carrier gas has been added, then the thin film deposited at the beginning contains more nitrogen, and the thin film eventually deposited will have a high stress value. The stress value of the thin film is greater than −3.0 GPa, or even up to −3.5 GPa.

In particular, the molecular weight of the carrier gas in the embodiment described above is smaller than the molecular weight of nitrogen gas, thus, collisions between the atoms of the assistant reaction gas can be reduced by adding the carrier gas having smaller molecular weight, so that the bombard power consumption can be reduced, the deposition efficiency can be increased, and accordingly a silicon nitride layer of high stress value can be deposited.

Next, applications of the high stress silicon nitride layer deposited with the methods provided by the present invention will be described with embodiments.

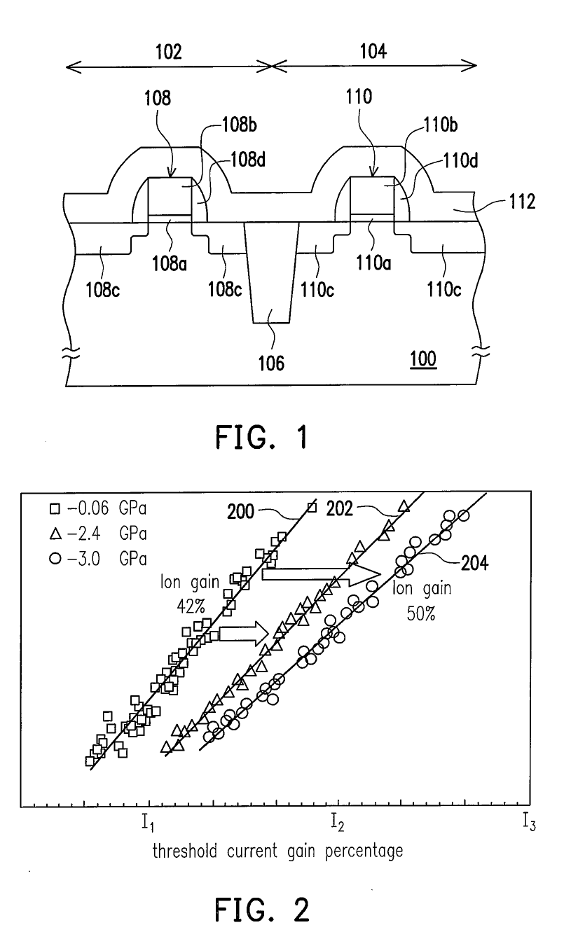

FIG. 1 is a cross-sectional diagram of a CMOS device according to an embodiment of the present invention.

Referring to FIG. 1, the substrate 100 has active regions 102 and 104, and the active regions 102 and 104 are isolated by an isolation structure 106. The isolation structure 106 is, for example, shallow trench isolation structure or other suitable isolation structure. Moreover, a PMOS 108 and an NMOS 110 are respectively formed in the active regions 102 and 104 of the substrate 100. Wherein, the PMOS 108 includes a dielectric layer 108a, a gate 108b, a source/drain region 108c, and a spacer 108d, and the NMOS 110 includes a gate dielectric layer 110a, a gate 110b, a source/drain region 110c, and a spacer 110d. Besides, a metal silicide layer (not shown) is respectively formed on the gate 108b and the source/drain region 108c of PMOS 108 and on the gate 110b and the source/drain region 110c of NMOS 110 for reducing resistance.

After that, a silicon nitride layer 112 formed with the method in the present invention is deposited on the substrate 100, and which can be used as a contact etching stop layer (CESL). The silicon nitride layer 112 may have high compressive stress, the stress value thereof may be greater than −3.0 GPa or even up to −3.5 GPa, thus the driving current of the device can be increased and the performance of the device can be improved.

Certainly, the silicon nitride layer deposited with the method in the present invention may also be applied to STI oxide layer, Poly-cap SiN layer, and dual CESL etc., besides foregoing applications to improve the performance of the device.

Below the relationship between the stress value of a stress layer and the performance of the device will be described with reference to FIG. 2.

FIG. 2 is a diagram illustrating the relationship between the threshold current gate percentage (Ion gain %) of the device and the stress value of the stress layer (GPa). In FIG. 2, curves 200, 202, and 204 represent respectively the affection of silicon nitride layers of different stress values (−0.06 GPa, −2.4 GPa, −3.0 GPa) used as the stress layer in the device to the performance of the device. As described above, curve 200 represents the affection of the silicon nitride layer deposited by conventional PECVD machine (with nitrogen gas as carrier gas) to the performance of the device, curve 202 represents the affection of the silicon nitride layer deposited by conventional PECVD machine with Ar (with nitrogen gas as carrier gas) to the performance of the device, and curve 204 represents the affection of the silicon nitride layer deposited by conventional PECVD machine with Ar (with H₂ as carrier gas) to the performance of the device. It can be understood from FIG. 2 that the silicon nitride layer deposited by conventional PECVD machine with Ar (with nitrogen gas as carrier gas) can make the threshold current gain percentage of the device to be about 42%, while the method in the present invention can increase the threshold current gain percentage of the device up to about 50%.

In overview, according to the methods of the present invention, high stress layer is formed by using PECVD machine, and an assistant reaction gas of greater molecular weight is added to increase the film stress, and a carrier gas having molecular weight smaller than the molecular weight of nitrogen gas is added to reduce collisions between the atoms of the assistant reaction gas, so that the bombard power consumption can be reduced, the deposition efficiency can be increased, and the stress value of the stress layer deposited can be further increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for increasing film stress, suitable for forming a stress layer in a plasma-enhanced chemical vapor deposition (PECVD) operation, the method comprising:
performing a PECVD process, adding a carrier gas which has the molecular weight smaller than the molecular weight of nitrogen gas; and
adding an assistant reaction gas which has the molecular weight greater than or equal to the molecular weight of nitrogen gas so as to perform ion bombard.

2. The method for increasing film stress as claimed in claim 1, wherein the assistant reaction gas comprises Ar, N₂, Kr, or Xe.

3. The method for increasing film stress as claimed in claim 1, wherein the carrier gas comprises H₂, He, Ne, or the combination thereof.

4. The method for increasing film stress as claimed in claim 1, wherein the stress layer comprises a silicon nitride layer.

5. The method for increasing film stress as claimed in claim 1, wherein a pre-gas is added before performing the PECVD process.

6. The method for increasing film stress as claimed in claim 5, wherein the pre-gas comprises N₂ or H₂.

7. A method for forming a high stress layer, comprising:
a substrate is put into a reactor of a PECVD machine and adding a reaction gas into the reactor;
adding an assistant reaction gas which has the molecular weight greater than or equal to the molecular weight of nitrogen gas into the reactor; and
adding a carrier gas which has the molecular weight smaller than the molecular weight of nitrogen gas into the reactor so as to the high stress layer is formed on the substrate.

8. The method for forming high stress layer as claimed in claim 7, wherein the assistant reaction gas comprises Ar, N₂, Kr, or Xe.

9. The method for forming high stress layer as claimed in claim 7, wherein the carrier gas comprises H₂, He, Ne, or the combination thereof.

10. The method for forming high stress layer as claimed in claim 7, wherein the high stress layer comprises a silicon nitride layer.

11. The method for forming high stress layer as claimed in claim 10, wherein the reaction gas comprises SiH₄ and NH₃.

12. The method for forming high stress layer as claimed in claim 7, wherein a pre-gas is added before the reaction gas is added into the reactor.

13. The method for forming high stress layer as claimed in claim 12, wherein the pre-gas comprises N₂ or H₂.
